(19) United States
(12) Patent Application Publication
(10) Pub. No.: US 2010/0084002 A1
(43) Pub. Date: Apr. 8, 2010

(54) METHOD FOR MANUFACTURING A SOLDERABLE LFC SOLAR CELL REAR SIDE AND A SOLAR MODULE FROM SUCH CONNECTED LFC SOLAR CELLS

(76) Inventors: Martin Kutzer, Penig (DE); Alexander Ohnesorge, Dresden (DE); Andreas Krause, Dresden (DE); Michael Heemeier, Dresden (DE); Kristian Schlegel, Zwickau (DE); Holger Neuhaus, Freiberg (DE)

Correspondence Address: MCGLEW & TUTTLE, PC, P.O. BOX 9227, SCARBOROUGH STATION, SCARBOROUGH, NY, 10510-9227, US

(21) Appl. No.: 12/555,137

(22) Filed: Sep. 8, 2009

(30) Foreign Application Priority Data
Sep. 9, 2008 (DE) 10 2008 046 480.5

(51) Int. Cl. H01L 31/042; H01L 31/0236; H01L 31/02

(52) U.S. Cl. 136/244; 136/256; 438/98; 257/E31.11

(57) ABSTRACT

A semiconductor component, especially in the form of a solar cell, comprises a semiconductor substrate of a planar design having a first side, a second side lying opposite thereto and a surface normal standing vertically on sides and, at least one dielectric passivation layer arranged on the second side, at least one electrically conductive contact layer arranged on the passivation layer, a well solderable cover layer arranged on the contact layer and an adhesive layer arranged between the cover layer and the contact layer.

### FIELD OF THE INVENTION

The invention relates to a semiconductor component, to a module comprising a plurality of semiconductor components and to a method for manufacturing a semiconductor component.

### BACKGROUND ART

On laser-fired-contact (LFC) solar cells, a metal layer made from aluminium is usually applied on the side facing away from the sun. It is known that the soldering of aluminium is technically very elaborate.

### SUMMARY OF THE INVENTION

The invention is therefore based on the object of improving a semiconductor component with an LFC rear side. The invention is also based on the object of providing a method for manufacturing such a semiconductor component.

According to the invention, said object is achieved by a semiconductor component comprising a semiconductor substrate of a planar design having a first side, a second side lying opposite thereto and a surface normal standing vertically on sides, and at least one dielectric passivation layer arranged on the second side, and at least one electrically conductive layer arranged on the passivation layer, and a well solderable cover layer arranged on the contact layer and an adhesive layer arranged between the cover layer and the contact layer. Furthermore, the contact ribbons of the semiconductor layer are applied on the cover layer by means of solder contacts and the cover layer is protected by an organic surface protection. The core of the invention consists in applying a well solderable metal foil on the LFC rear side of the semiconductor component. Particularly suitable for this is a well conductive metal foil made of copper.

Features and details of the invention result from the description of a plurality of embodiments based on the drawing.

### BRIEF DESCRIPTION OF THE DRAWING

FIG. 1 shows a schematic sectional representation through a semiconductor component according to a first embodiment.

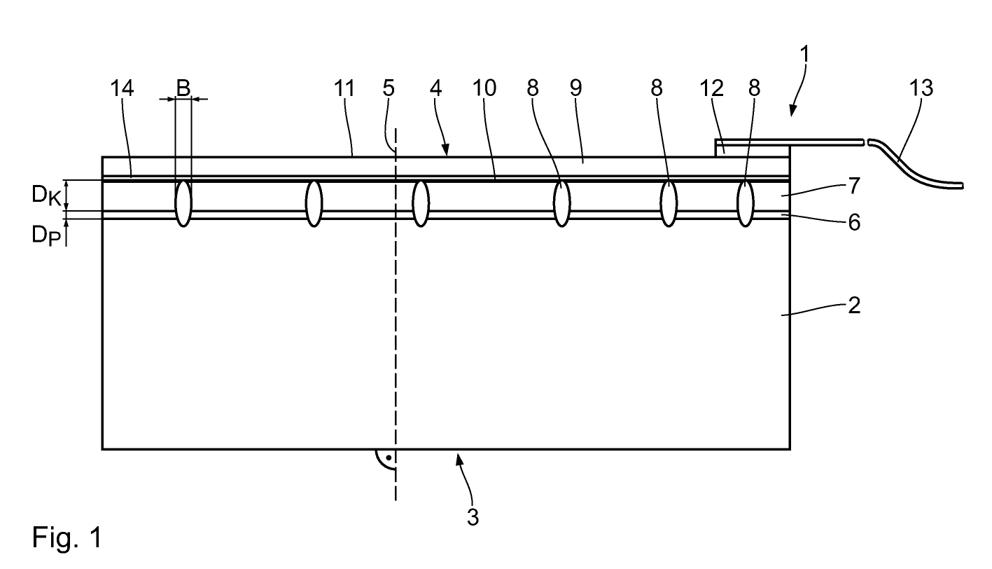

### DESCRIPTION OF THE PREFERRED EMBODIMENT

A semiconductor component 1 especially designed as a solar cell comprises a semiconductor substrate 2 of a planar design with a front side 3, a rear side 4 lying opposite thereto and a surface normal 5 standing vertically on the front side 3 and the rear side 4. The semiconductor substrate 2 is made of a semiconductor material, especially silicon. Other semiconductor materials are, however, also conceivable. An electrical passivation layer 6, which can also be designed as an internal light reflector, is applied on the rear side 4 of the semiconductor substrate 2. The electrical passivation layer 6 is electrically isolating. It is preferably made of silicon nitride or silicon dioxide. The passivation layer 6 exhibits a thickness, D_{P}, of a maximum of 1,000 nm, especially a maximum of 500 nm, especially of 100 nm.

Furthermore, the semiconductor component 1 comprises an electrically conductive contact layer 7 arranged on the electrical passivation layer 6. he contact layer 7 is made of an electrically well conductive metal, especially aluminium. On its side facing the semiconductor substrate 2 it is designed to be reflective. The contact layer 7 has a thickness, D_{K}, in the direction of the surface normal 5 of a maximum of 22 μm, especially a maximum of 10 μm, especially a maximum of 5 μm, especially a maximum of 1 μm.

A multitude of laser-fired contacts (LFCs) 8 is envisaged on the rear side 4. The laser-fired contacts 8 are manufacturable by radiation with a laser. During said radiation the semiconductor component 1 is heated in a defined point- or line-shaped area, so that there is formed a local melt mixture of the materials of the contact layer 7, the passivation layer 6 and semiconductor substrate 2 located underneath. After solidification the LFCs 8 form a good electrical contact between the semiconductor substrate 2 and the contact layer 7.

The LFCs 8 are manufacturable by applying radiation to the rear side 4 of the semiconductor component 1 using a suitable radiation source, especially a laser. In this process the material of the contact layer 7 penetrates the passivation layer 6 in a small, defined area of the rear side 4 and melts into the semiconductor substrate 2, so that the LFCs 8 form a good electrical contact between the semiconductor substrate 2 and the contact layer 7. The LFCs 8 exhibit, at least in a direction perpendicular to the surface normal 5, a smaller expansion B in a range of 1 μm to 100 μm, especially in a range of 25 μm to 75 μm.

The LFCs 8 are arranged in a pre-defined and especially regular pattern on the rear side 4 of semiconductor substrate 2.

Finally, the semiconductor component 1 comprises a cover layer 9 of planar design arranged on the contact layer 7. As a cover layer 9 there is envisaged a foil, in particular a copper foil. The cover layer 9 can also contain some brass and/or nickel and/or silver and/or tin or be made of brass, nickel, silver or tin. In case of a cover layer containing silver or copper the cover layer can optionally be protected by an organic surface protection layer (OSP layer). Moreover, there is envisaged between the cover layer 9 and the contact layer 7 a thin, electrically conductive adhesive layer 10. The cover layer 9 is advantageously designed to be self-adhesive. Preferably, the cover layer 9 largely, especially fully, covers the rear side 4. This minimises the transfer resistance between the contact layer 7 and the cover layer 9. Moreover, a cover layer 9 glued onto the entire surface increases the transverse conductivity of the rear side metallisation of the semiconductor component 1. This makes it possible to compensate performance losses due to the transfer resistance between the contact layer 7 and the cover layer 9.

The cover layer 9 is well solderable. By well solderable it is meant that a contact can be solded to the cover layer in particular using a soft-soldering process. To improve solderability, a solder layer 11 can be applied on the cover layer 9. The solder layer 11 especially contains some tin and/or bismuth.

Contact ribbons 13 are applied on the cover layer 9 by means of solder contacts 12. This way a plurality of semiconductor components 1 can be connected into a module.

In an especially advantageous embodiment the cover layer 9 is coated on its side facing the semiconductor substrate 2 with a diffusion barrier layer 14. The diffusion barrier layer 14 is especially made of nickel and/or cobalt. It forms a diffusion barrier to suppress the diffusion of metal ions, especially of copper ions from the cover layer 9 into the semiconductor substrate 2.

Instead of a full-surface cover layer 9, it can also be envisaged to apply the cover layer 9 only in some areas to the rear side 4 of the semiconductor component 1. The cover layer 9 is, however, especially applied on the rear side 4 of the semiconductor component 1 in the areas in which the arrangement of the contact lamina 13 is envisaged.

The following describes a method for manufacturing the semiconductor component 1. First, the semiconductor component 1 with LFCs 8 is provided. For the manufacture of the semiconductor component 1 with LFCs 8 reference is made to DE 10 2008 024053.2. The starting point is the semiconductor substrate 2, especially a silicon wafer, which is provided, at least on its rear side 4 and preferably also on its front side 3, with the passivation layer 6 and the contact layer 7 arranged thereon. Next, the semiconductor substrate 2 is provided with the LFCs 8 by means of a pulsed laser. For this there is preferably envisaged a liquid beam-guided laser. The liquid beam preferably exhibits dopants such as phosphorus, arsenic, antimony or also boron, indium, aluminium, gallium or compounds made thereof.

After that, the cover layer 9, which is preferably designed as a self-adhesive copper foil, is applied on the rear side 4 of the semiconductor component 1. Where appropriate, the rear side 4 of the semiconductor component 1 is first provided with a conductive adhesive layer 10. The adhesive strength of the cover layer 9 is supported by what is for process reasons a relatively rough surface of the rear side 4 of the semiconductor component 1.

Then the cover layer 9 is provided with the solder layer 11. It is, of course, also possible to provide the cover layer 9 with the solder layer 11 before applying it on the semiconductor component 1. The solder layer 11 is especially applied in the areas in which the solder contacts 12 for the contact ribbons 13 are envisaged. The contact ribbons 13 can easily be connected with the cover layer 9 via the solder contacts 12.

To manufacture a module, a plurality of semiconductor components 1 are connected by means of the contact ribbons 13.

What is claimed is:

1. A semiconductor component (1) comprising
a. a semiconductor substrate (2) of a planar design having
i. a first side (3),
ii. a second side (4) lying opposite thereto and
iii. a surface normal (5) standing vertically on sides (3) and (4),
b. at least one dielectric passivation layer (6) arranged on the second side (4),
c. at least one electrically conductive contact layer (7) arranged on the passivation layer (6),
d. a well solderable cover layer (9) arranged on the contact layer (7) and
e. an adhesive layer (10) arranged between the cover layer (9) and the contact layer (7).

2. A semiconductor component (1) according to claim 1, wherein the semiconductor component (1) is a solar cell.

3. A semiconductor component (1) according to claim 1, wherein the cover layer (9) is designed as a foil containing at least one of copper and brass and nickel and silver and tin.

4. A semiconductor component (1) according to claim 3, wherein the foil is self-adhesive.

5. A semiconductor component (1) according to claim 3, wherein the foil is provided with a solder layer (11).

6. A semiconductor component (1) according to claim 3, wherein the solder layer (11) contains at least one of tin and bismuth.

7. A semiconductor component (1) according to claim 3, wherein on its side facing the semiconductor substrate (2) the foil is coated with a diffusion barrier layer (14).

8. A semiconductor component (1) according to claim 3, wherein the diffusion barrier layer (14) is made of at least one of nickel and cobalt.

9. A semiconductor component (1) according to claim 1, wherein contact ribbons (13) are applied on the cover layer (9) by means of solder contacts (12).

10. A semiconductor component (1) according to claim 1, wherein the cover layer (9) is protected by an organic surface protection.

11. A module comprising at least two semiconductor components (1) according to claim 1, wherein the semiconductor components (1) are electrically connected by means of contact ribbons (13).

12. A method for manufacturing a semiconductor component (1) comprising the following steps:
a. provision of a semiconductor substrate (2) having
i. a first side (3) and
ii. a second side (4) lying opposite thereto,
b. provision of at least one cover layer (9) of a planar design,
c. application of the cover layer (9) on at least one of the sides (3, 4).

13. A method according to claim 12, wherein the cover layer (9) is designed as a self-adhesive foil.

14. A method according to claim 12, wherein at least one solder contact (12) for soldering contact ribbons (13) is applied on the cover layer (9).
